(19) United States
(12) Patent Application Publication
(10) Pub. No.: US 2026/0324025 A1
(43) Pub. Date: Oct. 15, 2026

(54) SILICON CARBIDE SEMICONDUCTOR DEVICE AND MANUFACTURING METHOD THEREOF

(71) Applicant: DENSO CORPORATION, Kariya-city (JP)

(72) Inventor: Kensuke HATA, Kariya-city (JP)

(21) Appl. No.: 19/457,838

(22) Filed: Jan. 23, 2026

Related U.S. Application Data
(63) Continuation of application No. PCT/JP2024/026321, filed on Jul. 23, 2024.

(30) Foreign Application Priority Data
Jul. 27, 2023 (JP) 2023-122606

(51) Int. Cl. H10D 62/60; H10D 30/66; H10D 62/832; H10P 30/22

(52) U.S. Cl. CPC H10D 62/60; H10D 30/668; H10D 62/8325; H10P 30/22

(57) ABSTRACT

A first impurity region is an ion-implanted layer, and a second impurity region is a recoil layer containing impurities of a first conductivity type. The second impurity region is made to a second conductivity type by making an impurity concentration of the second conductivity type higher than that of the first conductivity type. In a depth direction from a reference plane along an interface between the first impurity region and an electrode, a second peak position where the impurity concentration of the second conductivity type in the second impurity region is highest is located deeper than a first peak position where the impurity concentration of the first conductivity type in the first impurity region is highest. The electrode includes a metal silicide layer which is a compound with SiC.

### CROSS REFERENCE TO RELATED APPLICATION

The present application is a continuation application of International Patent Application No. PCT/JP2024/026321 filed on Jul. 23, 2024, which designated the U.S. and claims the benefit of priority from Japanese Patent Application No. 2023-122606, filed on Jul. 27, 2023. The entire disclosures of all of the above applications are incorporated herein by reference.

### TECHNICAL FIELD

The present disclosure relates to a semiconductor device made of silicon carbide (hereinafter also simply referred to as SiC) and having a first impurity region and a second impurity region, and a method of manufacturing the semiconductor device.

### BACKGROUND

In a SiC semiconductor device having a first impurity region and a second impurity region, a metal oxide semiconductor field effect transistor (MOSFET) is formed on a semiconductor substrate made of SiC.

### SUMMARY

According to one aspect of the present disclosure, a silicon carbide semiconductor device includes: a semiconductor substrate made of silicon carbide and having a first surface and a second surface opposite to each other; a first impurity region of a first conductivity type formed on the first surface of the semiconductor substrate; a second impurity region of a second conductivity type formed on the first surface of the semiconductor substrate and having a portion in contact with the first impurity region; and an electrode electrically connected to the first impurity region and the second impurity region. The first impurity region is an ion-implanted layer. The second impurity region is a recoil layer of the ion-implanted layer containing impurity of the first conductivity type. The second impurity region is of the second conductivity type by having a higher impurity concentration of the second conductivity type than that of the first conductivity type. In a depth direction from a reference plane defined along an interface between the first impurity region and the electrode, a second peak position at which the impurity concentration of the second conductivity type in the second impurity region is highest may be located deeper than a first peak position at which the impurity concentration of the first conductivity type in the first impurity region is highest. The electrode may include a metal silicide layer that is a compound with the silicon carbide and in contact with the semiconductor substrate.

### BRIEF DESCRIPTION OF DRAWINGS

FIG. 1 is a cross-sectional view of a SiC semiconductor device according to a first embodiment.

FIG. 2A is a diagram showing impurity concentration along line IIA-IIA in FIG. 1.

FIG. 2B is a diagram showing impurity concentration along line IIB-IIB in FIG. 1.

FIG. 3A is a cross-sectional view showing a manufacturing process of the SiC semiconductor device shown in FIG. 1.

FIG. 3B is a cross-sectional view showing a manufacturing process of the SiC semiconductor device continued from FIG. 3A.

FIG. 3C is a cross-sectional view showing a manufacturing process of the SiC semiconductor device continued from FIG. 3B.

FIG. 3D is a cross-sectional view showing a manufacturing process of the SiC semiconductor device continued from FIG. 3C.

FIG. 3E is a cross-sectional view showing a manufacturing process of the SiC semiconductor device continued from FIG. 3D.

FIG. 3F is a cross-sectional view showing a manufacturing process of the SiC semiconductor device continued from FIG. 3E.

FIG. 4 is a diagram showing impurity concentration along line IV-IV in FIG. 3D.

FIG. 5 is a cross-sectional view of a SiC semiconductor device according to a second embodiment.

### DETAILED DESCRIPTION

A SiC semiconductor device is made of SiC and has a first impurity region and a second impurity region. For example, in a SiC semiconductor device, a MOSFET is formed on a semiconductor substrate made of SiC. Specifically, the SiC semiconductor device has an n-type source region as a first impurity region, a p-type contact region as a second impurity region, and an electrode connected to the source region and the contact region. The MOSFET is an abbreviation for Metal Oxide Semiconductor Field Effect Transistor.

The source region and the contact region in such a SiC semiconductor device are formed as follows. The source region is formed by ion-implanting n-type impurities into the semiconductor substrate using a mask having an opening where the source region is to be formed. The contact region is formed by ion-implanting p-type impurities into the semiconductor substrate using a mask having an opening where the contact region is to be formed.

However, when forming the source region and the contact region, a mask for forming the source region and a mask for forming the contact region are prepared separately, which tends to increase the number of manufacturing steps. Furthermore, when forming the source region and the contact region, misalignment of the masks has to be taken into consideration, which tends to increase the size of the SiC semiconductor device.

For this reason, the present inventor considers manufacturing a SiC semiconductor device as follows. First, an n-type source region is formed in a semiconductor substrate without forming a mask. Then, a mask is placed that exposes a part of the source region, and p-type impurity ions are implanted to drive a part of the source region back into the p-type contact region, thereby manufacturing a SiC semiconductor device. According to this, it is only necessary to prepare a mask for forming the contact region. Thus, it is not necessary to prepare separately a mask for forming the source region and a mask for forming the contact region.

However, when manufacturing a SiC semiconductor device in this manner, if the peak position where the impurity concentration in the source region is highest is the same as the peak position where the impurity concentration in the contact region is highest, there is a possibility that damage will be significant. Specifically, if the peak positions are the same, a large amount of p-type impurity ions should be implanted when part of the source region is driven back into the contact region, which may increase the damage caused by the ion implantation. In this case, there is a possibility that the damage will cause fluctuations in the characteristics of the SiC semiconductor device.

The present disclosure aims to provide a SiC semiconductor device and a manufacturing method thereof, to restrict an increase in the number of manufacturing steps, an increase in size, and occurrence of characteristic fluctuations.

According to one aspect of the present disclosure, a SiC semiconductor device includes: a semiconductor substrate made of SiC and having a first surface and a second surface opposite to each other; a first impurity region of a first conductivity type formed on the first surface of the semiconductor substrate; a second impurity region of a second conductivity type formed on the first surface of the semiconductor substrate and having a portion in contact with the first impurity region; and an electrode electrically connected to the first impurity region and the second impurity region. The first impurity region is an ion-implanted layer. The second impurity region is a recoil layer of the ion-implanted layer containing impurity of the first conductivity type. The second impurity region is of the second conductivity type by having a higher impurity concentration of the second conductivity type than that of the first conductivity type. In a depth direction from a reference plane defined along an interface between the first impurity region and the electrode, a second peak position at which the impurity concentration of the second conductivity type in the second impurity region is highest is located deeper than a first peak position at which the impurity concentration of the first conductivity type in the first impurity region is highest. The electrode includes a metal silicide layer that is a compound with SiC and in contact with the semiconductor substrate.

According to this, the second impurity region is a recoil (counter-doped) layer containing the impurity of the first conductivity type. This eliminates the need for a mask when forming the first impurity region, and prevents an increase in the number of manufacturing steps. Furthermore, since a mask is not required when forming the first impurity region, it is only necessary to consider misalignment of one mask, and the SiC semiconductor device can be prevented from becoming large.

In the SiC semiconductor device, the second peak position is deeper than the first peak position. Therefore, compared to case where the second peak position is set to the same depth as the first peak position, the impurity amount of second conductivity type required to drive the first impurity region to form the second impurity region can be reduced, and damage that may occur to the semiconductor substrate can be reduced. Therefore, the occurrence of characteristic fluctuations is restricted.

In the SiC semiconductor device, the electrode includes the metal silicide layer. The metal silicide layer contains SiC of the semiconductor substrate. That is, the metal silicide layer is formed by reacting the portion to be damaged by ion implantation. Therefore, in the SiC semiconductor device, the remaining portion to be damaged by ion implantation can be reduced, and the occurrence of characteristic fluctuations is restricted.

According to another aspect of the present disclosure, a method of manufacturing the SiC semiconductor device includes:
preparing the semiconductor substrate;
ion-implanting a first impurity of the first conductivity type from the first surface of the semiconductor substrate to form the first conductivity type region;
arranging a mask on the first surface of the semiconductor substrate, the mask having an opening where the second impurity region is to be formed;
ion-implanting a second impurity of the second conductivity type from the first surface of the semiconductor substrate to drive a portion of the first conductivity type region to form the second impurity region, and form the first impurity region by a part of the first conductivity type region different from the second impurity region; and
arranging a metal layer on the first surface of the semiconductor substrate and reacting the metal layer with the semiconductor substrate to form the metal silicide layer of the electrode after the ion-implanting of the second impurity.

In the ion-implanting of the second impurity, the second impurity is ion-implanted so that the second peak position is located deeper than the first peak position.

According to this method, the first impurity region is driven back to form the second impurity region. This eliminates the need for a mask when forming the first impurity region, and prevents an increase in the number of manufacturing steps. Furthermore, since a mask is not required when forming the first impurity region, it is only necessary to consider misalignment of one mask, and the SiC semiconductor device can be prevented from becoming large.

Furthermore, in this method of manufacturing a SiC semiconductor device, the second peak position is set deeper than the first peak position. Therefore, compared to a case where the second peak position is set to the same depth as the first peak position, the impurity amount of second conductivity type required to strike back the first impurity region and form the second impurity region can be reduced, thereby reducing damage that may occur to the semiconductor substrate. Therefore, it is possible to manufacture a SiC semiconductor device in which the occurrence of characteristic fluctuations is restricted.

Furthermore, in this method of manufacturing a SiC semiconductor device, the electrode including the metal silicide layer is formed. The metal silicide layer contains SiC of the semiconductor substrate. That is, the metal silicide layer is formed by reacting the portion to be damaged by ion implantation. Therefore, in this method of manufacturing a SiC semiconductor device, it is possible to reduce the remaining portion damaged by ion implantation, and to manufacture a SiC semiconductor device in which the occurrence of characteristic fluctuations is restricted.

Embodiments of the present disclosure will be described with reference to the drawings. In the following embodiments, the same reference numerals are assigned to parts that are the same as or equivalent to each other for description.

### First Embodiment

A first embodiment will be described with reference to the drawings. In the first embodiment, an inverted MOSFET with a trench gate structure is formed as a SiC semiconductor device.

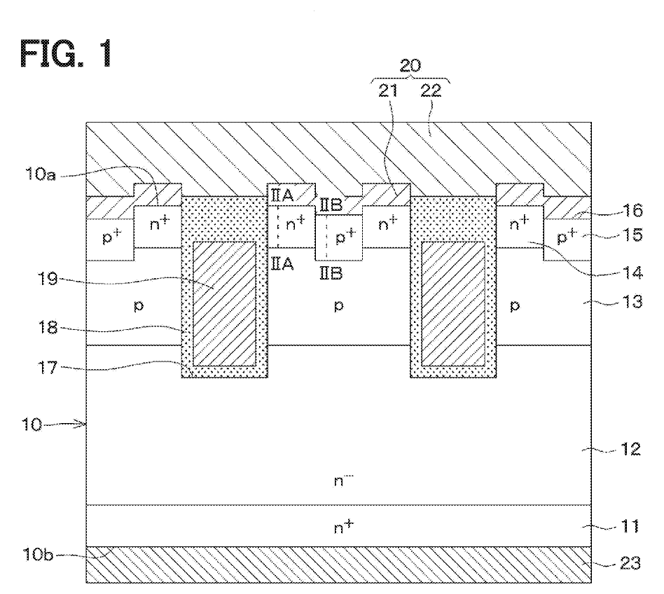

As illustrated in FIG. 1, the SiC semiconductor device includes a semiconductor substrate 10 made of SiC. The semiconductor substrate 10 of the SiC semiconductor device includes an n⁺-type substrate 11 made of SiC. In the present embodiment, the substrate 11 has an off-angle of 0 to 8 degrees with respect to, for example, a (0001) Si plane. The substrate 11 has an n-type impurity, such as nitrogen or phosphorus, concentration of, for example, 1.0x10¹⁹/cm³, and a thickness of about 50 micrometers (μm) to 300 micrometers (μm). In the present embodiment, a drain region is included in the substrate 11.

An n⁻-type drift layer 12 made of SiC and a p-type base layer 13 are formed on the surface of the substrate 11 by, for example, epitaxial growth. The semiconductor substrate 10 has a first surface 10a adjacent to the base layer 13, and a second surface 10b adjacent to the substrate 11.

The drift layer 12 has, for example, an n-type impurity concentration of about 1.0x10¹⁵/cm³ to 50.0x10¹⁵/cm³ and a thickness of about 5 to 50 μm. The base layer 13 is formed on the drift layer 12 and has a p-type impurity concentration of about 2.0x10¹⁷/cm³ and a thickness of about 0.5 to 2 μm.

An n⁺-type source region 14 and p⁺-type contact region 15 are formed at a surface layer of the base layer 13. The source region 14 is formed in contact with the side surface of a trench 17, which will be described later. The contact region 15 is formed opposite to the trench 17 through the source region 14, and is in contact with the source region 14. The contact region 15 is formed deeper than the source region 14.

In this embodiment, a recess 16 is formed on the first surface 10a. The recess 16 is recessed from the first surface 10a of the semiconductor substrate 10. The contact region 15 is formed to be exposed from the bottom surface of the recess 16. The source region 14 is formed to be exposed from a portion of the first surface 10a of the semiconductor substrate 10 different from the portion where the recess 16 is formed. In other words, in the normal direction to the first surface 10a of the semiconductor substrate 10, the contact region 15 is formed to overlap the recess 16, and the source region 14 is formed in a region different from the region overlapping with the recess 16. In other words, when viewed in the normal direction to the first surface 10a of the semiconductor substrate 10, the contact region 15 overlaps with the recess 16, and the source region 14 does not overlap with the recess 16.

Furthermore, as will be described later, the contact region 15 of this embodiment is formed by ion-implanting a larger amount of p-type impurities than n-type impurities into the n-type region, thereby driving the n-type region back into the p-type region. Therefore, the contact region 15 also contains n-type impurities. In this embodiment, the source region 14 corresponds to a first impurity region, and the contact region 15 corresponds to a second impurity region. The source region 14 and the contact region 15 are ion-implanted layers formed by ion implantation as will be described later, and the contact region 15 corresponds to a recoil (counter-implanted) layer formed by counter-implanting the n-type region.

The semiconductor substrate 10 has gate trenches 17 penetrating the source region 14 and the base layer 13 to reach the drift layer 12. Each of the trenches 17 has a width of, for example, 0.8 μm. Although two trenches 17 are shown in FIG. 1, the trenches 17 are formed in the form of stripes, specifically, plural trenches are arranged at equal interval in the left-right direction of the drawing.

Each of the trenches 17 is filled with a gate insulating film 18 formed to cover the wall surface of the trench 17 and a gate electrode 19 made of polysilicon or the like formed on the gate insulating film 18. In the present embodiment, a trench gate structure is configured in this manner. In this embodiment, a portion of the wall surface of the trench 17 in contact with the base layer 13 is a surface of the base layer 13 interposed between the first impurity region and the drift layer 12.

An upper electrode 20 is formed on the first surface 10a of the semiconductor substrate 10, and is electrically connected to the source region 14 and the contact region 15. In this embodiment, the upper electrode 20 includes: a metal silicide layer 21 formed at the interface with the semiconductor substrate 10; and a main portion 22 disposed on the metal silicide layer 21.

Specifically, the metal silicide layer 21 is a metal layer which is a compound that has undergone a silicidation reaction with SiC (i.e., the semiconductor substrate 10), and the contact resistance with SiC is reduced to provide an ohmic contact. The metal silicide layer 21 is formed along the first surface 10a of the semiconductor substrate 10. In this embodiment, since the recess 16 is formed on the first surface 10a of the semiconductor substrate 10, a portion of the metal silicide layer 21 located above the recess 16 is recessed.

The metal silicide layer 21 is made of a refractory metal or noble metal silicide, such as a nickel silicide layer, a titanium silicide layer, a tantalum silicide layer, a tungsten silicide layer, or a molybdenum silicide layer. The metal silicide layer 21 may be made of one kind of metal or may be made of plural kinds of metals. For example, the type of metal constituting the metal silicide layer 21 may be different between n-type SiC and p-type SiC. In this embodiment, the metal silicide layer 21 is made of nickel silicide layer. The thickness of the metal silicide layer 21 can be changed as appropriate, for example, about 10 to 100 nm.

The main portion 22 is made of, for example, aluminum silicon or the like, and is formed to be thicker than the metal silicide layer 21. Although not shown, the main portion 22 may have a plated film of nickel, gold, or the like formed on the surface opposite to the metal silicide layer 21.

A lower electrode 23 is disposed on the second surface 10b of the semiconductor substrate 10 and electrically connected to the substrate 11. In the SiC semiconductor device according to the present embodiment, with such a structure, MOSFET of an n-channel type inverted trench gate structure is formed. In this embodiment, the n-type corresponds to the first conductivity type, and the p-type corresponds to the second conductivity type.

In such a SiC semiconductor device, when a voltage equal to or greater than a predetermined threshold voltage is applied to the gate electrode 19 while a voltage lower than that of the lower electrode 23 is applied to the upper electrode 20, an n-type inversion layer (i.e., a channel) is formed in a part of the base layer 13 in contact with the trench 17. Electrons are supplied from the source region 14 to the drift layer 12 through the inversion layer so that the SiC semiconductor device is turned on.

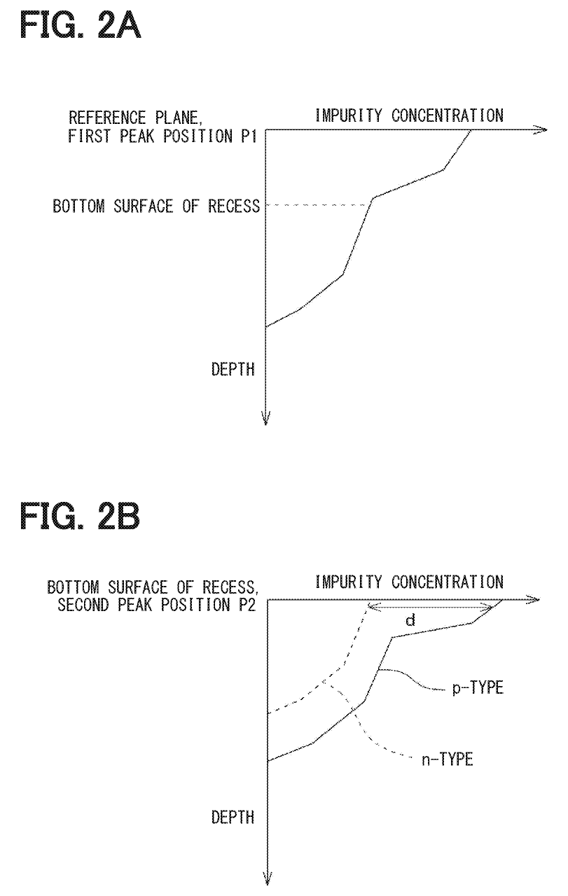

The basic structure of the semiconductor device according to the present embodiment is described above. Next, the impurity concentrations of the source region 14 and the contact region 15 in the SiC semiconductor device will be described with reference to FIGS. 2A and 2B. In the following description, a plane along the interface between the source region 14 and the upper electrode 20 is used as a reference plane.

As will be described later, the contact region 15 of this embodiment is formed by ion-implanting p-type impurities into an n-type region and driving a part of the n-type region back into the p-type region. As will be described later, the source region 14 is formed from a portion of the n-type region that is different from the contact region 15.

As shown in FIG. 2A, the first peak position P1 where the n-type impurity concentration is highest is set as the reference plane, relative to the source region 14. That is, the first peak position P 1 where the n-type impurity concentration of the source region 14 is highest is the interface with the metal silicide layer 21. Hereinafter, the first peak position P1 where the n-type impurity concentration in the source region 14 is highest may be simply referred to as the first peak position P1 of the source region 14.

The contact region 15 (p-type region) is formed by retro-doping (implantation/drive-in) into the first impurity region (n-type region). Therefore, as shown in FIG. 2B, the contact region 15 contains the n-type impurities, and is made into a p-type region by making the p-type impurity concentration higher than the n-type impurity concentration. In the contact region 15, the second peak position P 2 where the p-type impurity concentration is highest is located at the interface with the bottom surface of the recess 16. That is, the second peak position P2 where the p-type impurity concentration of the contact region 15 is highest is the interface with the metal silicide layer 21. Hereinafter, the second peak position P2 where the p-type impurity concentration in the contact region 15 is highest may be simply referred to as the second peak position P2 of the contact region 15.

In this embodiment, the first peak position P1 of the source region 14 and the second peak position P2 of the contact region 15 are different. The second peak position P2 is formed at a deeper position than the first peak position P1. Since the source region 14 and the contact region 15 are formed by ion implantation, the impurity concentration decreases from the peak position P1, P2 along the depth direction. Therefore, the n-type impurity concentration at the second peak position P2 is lower than the n-type impurity concentration at the first peak position P1.

Furthermore, the contact region 15 contains n-type impurities as described above. In the contact region 15, the contact resistance with the upper electrode 20 (the metal silicide layer 21) depends on the concentration difference “d” between the p-type impurity concentration and the n-type impurity concentration, and decreases as the concentration difference “d” increases. For this reason, in this embodiment, the impurity concentration at the second peak position P2 is set higher than the impurity concentration at the first peak position P1.

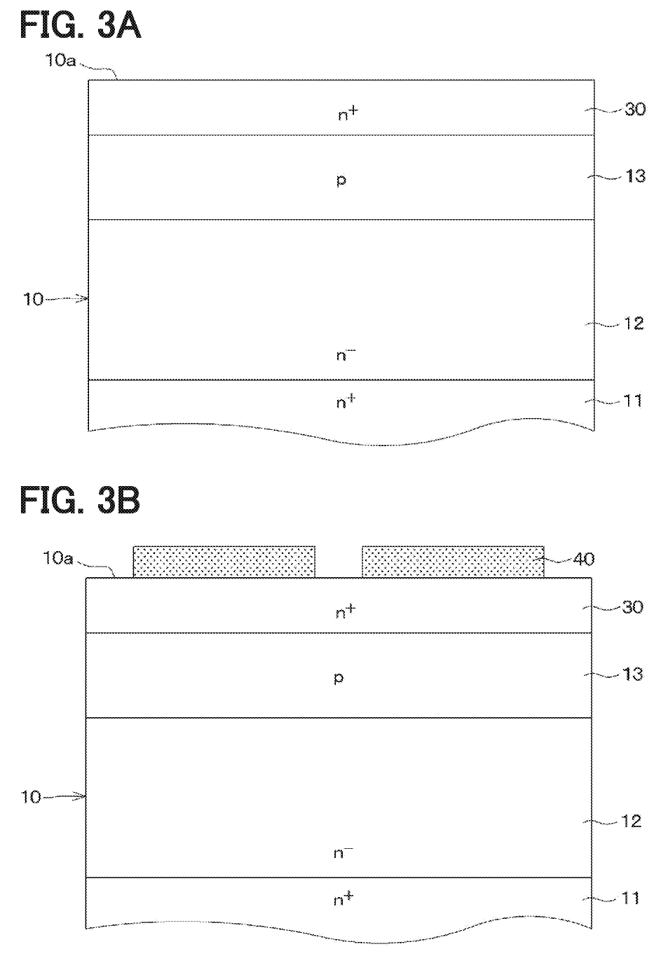

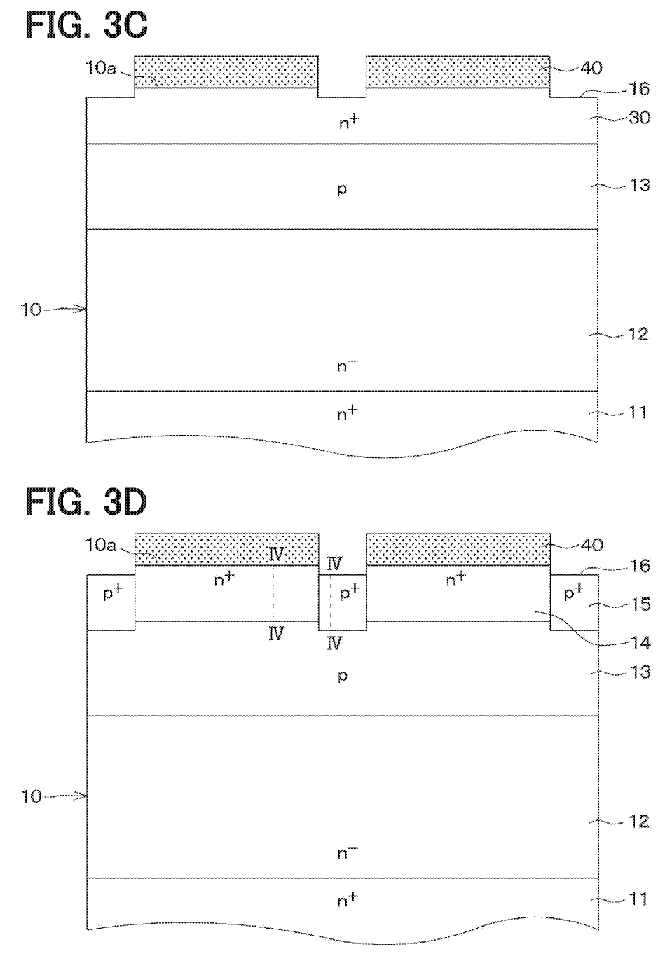

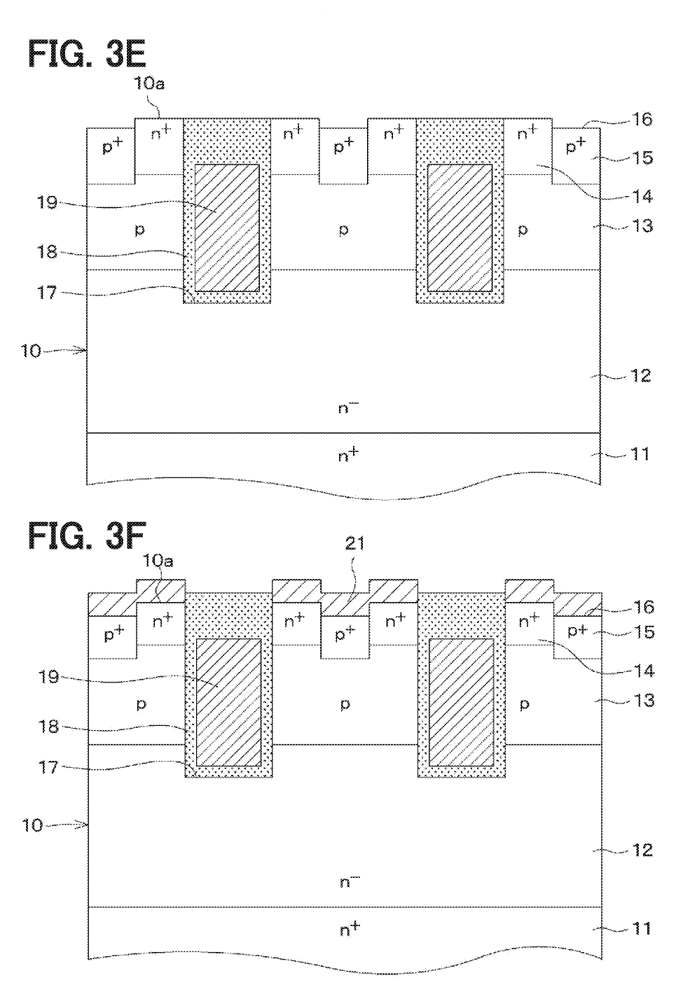

Next, a method for manufacturing the source region 14 and the contact region 15 in the SiC semiconductor device will be described with reference to FIGS. 3A to 3F. In FIGS. 3A to 3F, the second surface 10b of the semiconductor substrate 10 is omitted in illustration.

First, as shown in FIG. 3A, a semiconductor substrate 10 formed up to the base layer 13 is prepared. Without placing a mask, n-type impurities are ion-implanted from the first surface 10a of the semiconductor substrate 10 to form an n-type region 30 on the base layer 13. A part of the n-type region 30 will be the source region 14 and corresponds to a first conductivity type region.

Next, as shown in FIG. 3B, a mask 40 is placed on the first surface 10a of the semiconductor substrate 10. Then, the mask 40 is patterned so that an area on the first surface 10a of the semiconductor substrate 10 where the contact region 15 is to be formed is opened.

Subsequently, as shown in FIG. 3C, RIE (abbreviation of reactive ion etching) or the like is performed to form the recess 16 in the first surface 10a of the semiconductor substrate 10 exposed from the mask 40. The depth of the recess 16 is set according to the amount of SiC to be reacted when forming the metal silicide layer 21. After the step of FIG. 3C is completed, the depth of the recess 16 is shallower than that of the recess 16 of the SiC semiconductor device shown in FIG. 1.

Next, as shown in FIG. 3D, the mask 40 used to form the recess 16 is used as it is to ion-implant p-type impurities from the bottom surface of the recess 16, thereby driving a portion of the n-type region 30 exposed under the mask 40 into the p-type region. As a result, the contact region 15 is formed in the drive-in portion of the n-type region 30, and the source region 14 is formed in another portion of the n-type region 30 different from the contact region 15.

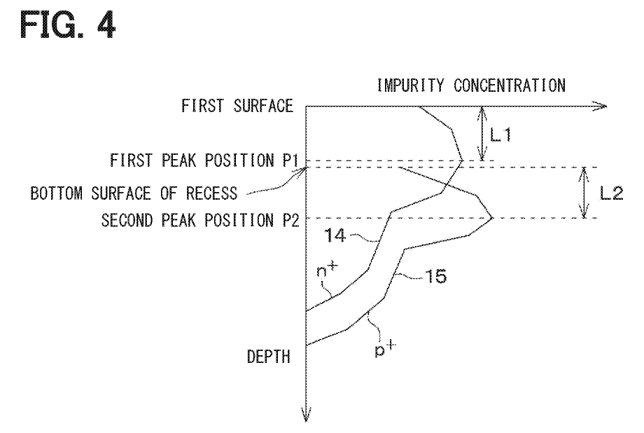

In this embodiment, when ions of p-type impurities are implanted, the p-type impurities are implanted at approximately the same acceleration voltage as when ions of n-type impurities are implanted. Therefore, the relationship between the first peak position P1 of the source region 14 and the second peak position P2 of the contact region 15 after the step of FIG. 3D is as shown in FIG. 4. Although not shown, ion implantation of n-type impurities and p-type impurities causes defects and the like due to damage on the first surface 10a of the semiconductor substrate 10. FIG. 4 also shows the n-type impurity concentration in the source region 14 and the p-type impurity concentration in the contact region 15 along a line IV-IV in FIG. 3D. The n-type impurity concentration in the contact region 15 located deeper than the bottom surface of the recess 16 in FIG. 4 is similar to that in the source region 14. Furthermore, after the step of FIG. 3D is performed can be said to be before the metal silicide layer 21 is formed.

When n-type impurities and p-type impurities are ion-implanted at approximately the same acceleration voltage, the distance between the peak position where the impurity concentration is highest and the implanted surface is approximately the same. Therefore, as shown in FIG. 4, a first distance L1 between the first surface 10a of the semiconductor substrate 10 and the first peak position P1 is approximately equal to a second distance L2 between the bottom surface of the recess 16 and the second peak position P2. In this embodiment, the first distance L1 and the second distance L2 are adjusted according to the amount of SiC that reacts when forming the metal silicide layer 21, which will be described later.

As described above, the contact resistance between the contact region 15 and the upper electrode 20 depends on the concentration difference “d” between the p-type impurity concentration and the n-type impurity concentration. Therefore, in this embodiment, the p-type impurity concentration at the second peak position P2 is made higher than the n-type impurity concentration at the first peak position P1, thereby increasing the concentration difference “d” to reduce the contact resistance. Furthermore, when the first peak position P1 and the second peak position P2 are at the same depth, in order to achieve the same contact resistance as in this embodiment, the p-type impurity concentration is to be further increased, which makes the first surface 10a of the semiconductor substrate 10 more likely to become rough.

Next, as shown in FIG. 3E, a mask (not shown) is placed and anisotropic etching such as RIE is performed to form the trench 17. Thereafter, the gate insulating film 18 and the gate electrode 19 are formed in the trench 17 by CVD (chemical vapor deposition) method or the like. Then, unnecessary portions of the gate insulating film 18 and the gate electrode 19 formed on the first surface 10a of semiconductor substrate 10 are removed.

Next, as shown in FIG. 3F, a metal layer such as nickel is formed on the first surface 10a of the semiconductor substrate 10 by a sputtering method or the like, and a heat treatment is performed to react the semiconductor substrate 10 (i.e., SiC) with the metal layer to form the metal silicide layer 21. That is, the damaged portion of the semiconductor substrate 10 is reacted to form the metal silicide layer 21. In this embodiment, the thickness of the metal silicide layer 21 is adjusted by adjusting the heating temperature, etc., so that the first peak position P1 of the source region 14 and the second peak position P2 of the contact region 15 are located at the interface with the metal silicide layer 21. That is, by adjusting the amount of reaction with the metal layer of the semiconductor substrate 10 and adjusting the thickness of the metal silicide layer 21, the first peak position P1 of the source region 14 and the second peak position P2 of the contact region 15 are positioned at the interface with the metal silicide layer 21. As a result, the impurity concentration in the depth direction of the source region 14 becomes as shown in FIG. 2A, and the impurity concentration in the depth direction of the contact region 15 becomes as shown in FIG. 2B.

In this step, the semiconductor substrate 10 reacts with the metal layer to form the metal silicide layer 21, so that the first surface 10a of the semiconductor substrate 10 and the bottom surface of the recess 16 are dug deeper than before the metal silicide layer 21 was formed. In this step, the metal silicide layer 21 is formed so that the first peak position P1 of the source region 14 and the second peak position P2 of the contact region 15 are located at the interface with the metal silicide layer 21, but some deviation from the target position may be acceptable due to manufacturing errors.

Thereafter, although not shown, a metal layer that will become the main portion 22 is disposed to form the upper electrode 20 and the lower electrode 23, thereby manufacturing the SiC semiconductor device shown in FIG. 1.

According to the present embodiment, the contact region 15 is a recoil layer containing n-type impurities. This eliminates the need for a mask when forming the source region 14, and prevents an increase in the number of manufacturing steps. Furthermore, since a mask is not required when forming the source region 14, only the misalignment of the mask when forming the contact region 15 needs to be considered, and the SiC semiconductor device can be prevented from becoming large.

Furthermore, in the SiC semiconductor device of this embodiment, the second peak position P2 is deeper than the first peak position P1. Therefore, compared to a case where the second peak position is set to the same depth as the first peak position, the amount of p-type impurity required to drive back the source region 14 into the contact region 15 can be reduced, and the damage that may occur to the semiconductor substrate 10 can be reduced. Therefore, the occurrence of characteristic fluctuations is suppressed.

Furthermore, in this SiC semiconductor device, the upper electrode 20 includes the metal silicide layer 21. The metal silicide layer 21 contains SiC, which constitutes the semiconductor substrate 10. That is, the metal silicide layer 21 is formed by reacting the portion damaged by ion implantation. Therefore, in this SiC semiconductor device, the remaining portion damaged by ion implantation can be reduced, and the occurrence of characteristic fluctuations is suppressed.
(1) In this embodiment, the recess 16 is formed, and p-type impurities are ion-implanted into the bottom surface of the recess 16, thereby making the second peak position P2 deeper than the first peak position P1. Therefore, n-type impurities and p-type impurities can be ion-implanted at the same acceleration voltage, and the manufacturing process can be further simplified.
(2) In this embodiment, the first peak position P1 and the second peak position P2 are positioned at the interface with the metal silicide layer 21 of the upper electrode 20. Therefore, the contact resistance between the upper electrode 20 and the source region 14 and between the upper electrode 20 and the contact region 15 can be reduced.

In this embodiment, the contact region 15 contains n-type impurities. The contact resistance between the contact region 15 and the metal silicide layer 21 is caused by the concentration difference “d” between the n-type impurity concentration and the p-type impurity concentration at the interface between the contact region 15 and the metal silicide layer 21, and decreases as the concentration difference “d” increases. In this embodiment, the second peak position P2 is formed at a position deeper than the first peak position P1. Therefore, compared to a case where the first peak position P1 is the same as the second peak position P2, it is easier to increase the concentration difference “d” without increasing the p-type impurity concentration, and it is easier to reduce the contact resistance.

### Second Embodiment

A second embodiment will be described. In this embodiment, the method of forming the contact region 15 is changed from that of the first embodiment. Other aspects are the same as in the first embodiment, and thus a detailed description will be omitted.

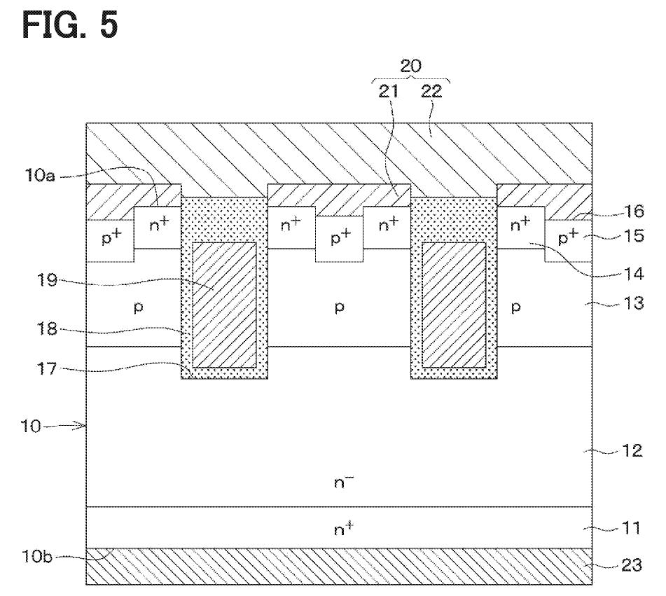

In the SiC semiconductor device of this embodiment, as shown in FIG. 5, the surface of the metal silicide layer 21 opposite to the semiconductor substrate 10 is planarized. In this embodiment, the metal silicide layer 21 is made thicker in the portion located above the contact region 15 than in the portion located above the source region 14.

The configuration of the SiC semiconductor device according to the present embodiment is described above. Next, a manufacturing process of the SiC semiconductor device according to this embodiment will be described.

In this embodiment, after the step of FIG. 3B is performed, p-type impurities are ion-implanted to drive the portion of the n-type region 30 exposed from the mask 40 into a p-type region, thereby forming the contact region 15 and the source region 14. Specifically, in this embodiment, unlike the step of FIG. 3C, p-type impurities are ion-implanted without forming the recess 16. In this embodiment, the p-type impurity is ion-implanted at a higher acceleration voltage than when the n-type impurity is ion-implanted to form the n-type region 30, so that the second peak position P2 is deeper than the first peak position P1.

In this case, the acceleration voltage when ion-implanting p-type impurities is set higher than the acceleration voltage when ion-implanting n-type impurities. Therefore, a portion of the first surface 10a of the semiconductor substrate 10 into which the p-type impurities are ion-implanted is likely to suffer significant damage and its crystallinity is likely to be destroyed.

Next, the steps of FIGS. 3E and 3F are carried out. When the metal silicide layer 21 is formed in the step of FIG. 3F, the more the crystallinity is degraded, the more likely the metal layer and the semiconductor substrate 10 will react with each other, and the more likely the metal silicide layer 21 will be formed. Therefore, the metal silicide layer 21 is more likely to be formed in the contact region 15 than in the source region 14, and the metal silicide layer 21 is formed deep in the contact region 15. As a result, the recess 16 can be formed in the semiconductor substrate 10 in the area where the contact region 15 is to be formed. In this embodiment, the SiC that reacts with the metal layer is adjusted by roughening the first surface 10a of the semiconductor substrate 10, so that the surface of the metal silicide layer 21 opposite to the semiconductor substrate 10 is planarized.

Thereafter, in the same manner as in the first embodiment, the main portion 22 is disposed to form the upper electrode 20 and the lower electrode 23, thereby manufacturing the SiC semiconductor device shown in FIG. 5.

According to the present embodiment, since the contact region 15 is the recoil layer, the same effects as those of the first embodiment can be obtained.

(1) In this embodiment, the acceleration voltage is changed to make the second peak position P2 deeper than the first peak position P1. Therefore, a step for forming the recess 16 is not required, and the number of manufacturing steps can be reduced.

### Other Embodiments

The present disclosure has been described in accordance with the embodiments. However, it is understood that the present disclosure is not limited to these embodiments or structures. The present disclosure also encompasses various modifications and equivalents within the scope of the disclosure. In addition, various combinations and forms (including those comprising only one element, more than one, or fewer than one element) are also within the scope and spirit of the present disclosure.

For example, in each of the embodiments, a SiC semiconductor device is configured by forming an n-channel type trench gate MOSFET in which the first conductivity type is n-type and the second conductivity type is p-type. However, the SiC semiconductor device may be configured by forming a p-channel type trench gate MOSFET in which the first conductivity type is p-type and the second conductivity type is n-type. Other than the MOSFET, the SiC semiconductor device may be formed with an IGBT with a similar structure. In the case of IGBT, the n⁺ type substrate 11 in each of the embodiments is modified to the p⁺ type collector layer. Other than that, IGBT is similar to the MOSFET as described in each of the embodiments.

Furthermore, in each of the embodiments, a method has been described in which, after the n-type region 30 is formed, p-type impurities are ion-implanted to drive a part of the n-type region 30 back into a p-type region. However, it is also possible to form the p-type region first, and then ion-implant n-type impurities to drive a part of the p-type region back into the n-type region.

In each of the embodiments, the n-type impurity concentration at the first peak position P1 and the p-type impurity concentration at the second peak position P2 may be the same. The n-type impurity concentration at the first peak position P1 may be higher than the p-type impurity concentration at the second peak position P2.

What is claimed is:

1. A silicon carbide semiconductor device comprising:
a semiconductor substrate made of silicon carbide and having a first surface and a second surface opposite to each other;
a first impurity region of a first conductivity type formed on the first surface of the semiconductor substrate;
a second impurity region of a second conductivity type formed on the first surface of the semiconductor substrate and in contact with the first impurity region; and
an electrode electrically connected to the first impurity region and the second impurity region, wherein
the first impurity region is an ion-implanted layer,
the second impurity region is a recoil layer of the ion-implanted layer containing impurity of the first conductivity type, and is made to be the second conductivity type by making an impurity concentration of the second conductivity type higher than that of the first conductivity type,
a reference plane is defined along an interface between the first impurity region and the electrode,
a first peak position is defined where an impurity concentration of the first conductivity type in the first impurity region is highest in a depth direction of the semiconductor substrate from the reference plane,
a second peak position is defined where an impurity concentration of the second conductivity type in the second impurity region is highest in the depth direction,
the second peak position is located deeper than the first peak position in the depth direction,
the electrode includes a metal silicide layer that is a compound with the silicon carbide and is in contact with the semiconductor substrate, and
the first peak position and the second peak position are located at an interface with the metal silicide layer.

2. The silicon carbide semiconductor device according to claim 1, wherein
the semiconductor substrate has a recess formed on the first surface, and
the second impurity region is formed at a position overlapping with the recess when viewed in a normal direction normal to the first surface of the semiconductor substrate.

3. The silicon carbide semiconductor device according to claim 2, wherein the first impurity region is located only at a position not overlapping with the recess when viewed in the normal direction.

4. A manufacturing method of the silicon carbide semiconductor device according to claim 1, the manufacturing method comprising:
preparing the semiconductor substrate;
forming a first conductivity type region by ion-implanting a first impurity of the first conductivity type from the first surface of the semiconductor substrate;
arranging a mask having an opening corresponding to a region where the second impurity region is to be formed, on the first surface of the semiconductor substrate;
ion-implanting a second impurity of the second conductivity type from the first surface of the semiconductor substrate to form the second impurity region by implanting a part of the first conductivity type region, and to form the first impurity region by a part of the first conductivity type region different from the second impurity region; and
forming the metal silicide layer of the electrode, after the ion-implanting of the second impurity, by arranging a metal layer on the first surface of the semiconductor substrate to react with the semiconductor substrate, wherein
in the ion-implanting of the second impurity, the second impurity is ion-implanted such that the second peak position is located at a position deeper than the first peak position, and
in the forming of the metal silicide layer, a thickness of the metal silicide layer is adjusted so that the first peak position and the second peak position are located at an interface between the metal silicide layer and the semiconductor substrate.

5. The manufacturing method according to claim 4, wherein
the ion-implanting of the second impurity includes:
forming a recess in a region of the first surface of the semiconductor substrate where the second impurity region is to be formed, and
ion-implanting the second impurity into a bottom surface of the recess.

6. The manufacturing method according to claim 5, wherein
in the forming of the recess, the mask is arranged to form the recess, and
in the ion-implanting of the second impurity, the second impurity is ion-implanted from the bottom surface of the recess using the mask.

7. The manufacturing method according to claim 4, wherein
in the ion-implanting of the second impurity, the second peak position is made deeper than the first peak position by ion-implanting the second impurity at an acceleration voltage higher than an acceleration voltage for ion-implanting the first impurity.
